(19) United States
(12) Patent Application Publication
(10) Pub. No.: US 2026/0353571 A1
(43) Pub. Date: Nov. 5, 2026

(54) LAMINATE AND METHOD FOR MANUFACTURING CIRCUIT BOARD

(71) Applicant: ELEPHANTECH INC., Tokyo (JP)

(72) Inventors: Akinori TERADA, Tokyo (JP); Shinya SHIMIZU, Tokyo (JP)

(73) Assignee: ELEPHANTECH INC., Tokyo (JP)

(21) Appl. No.: 19/665,329

(22) Filed: May 1, 2026

(30) Foreign Application Priority Data
May 2, 2025 (JP) 2025-076913

(51) Int. Cl. H05K 3/38; H05K 1/09

(52) U.S. Cl. CPC H05K 3/387; H05K 1/092; H05K 2201/032; H05K 2203/0709; H05K 2203/072; H05K 2203/0723

(57) ABSTRACT

For improvement in adhesion strength between a metal layer such as a plating layer or a metal particle layer and a resin layer or a substrate layer in a method for manufacturing a circuit board, the present disclosure provides a laminate including a resin layer containing an epoxy resin and a metal particle layer formed on the resin layer by applying a metal particle dispersion, wherein the metal particle dispersion contains at least metal particles and an additive, and the additive contained in the metal particle layer is also contained in the resin layer.

### BACKGROUND

The present disclosure relates to a laminate and a method for manufacturing a circuit board.

In order to produce a circuit board by an environmentally friendly and non-subtractive method with fewer steps, an ink and a method for producing a circuit board have been known (see Japanese Unexamined Patent Publication No. 2024-124889). This ink contains copper nanoparticles coated with a coating material made of monocarboxylic acid with a carbon number of 7, 8 or 9, a solvent, and a dispersant for dispersing the copper nanoparticles in the solvent, and the dispersant contains at least polycarboxylic acid. The ratio of copper oxide in the copper nanoparticles is, for example, approximately 20% by weight or more and 40% by weight or less. The polycarboxylic acid is preferably polycarboxylic acid having a comb structure.

### SUMMARY

A method for manufacturing a circuit board is required to improve adhesion strength between a metal layer such as a plating layer or a metal particle layer and a resin layer or a substrate layer.

The issues that are obvious to those skilled in the art, which can be read from the characteristic embodiments of the present disclosure and the description thereof in the specification and the drawings, can also be issues to be solved by the invention disclosed in any divisional application based on the present disclosure.

A laminate of the present disclosure includes a resin layer containing an epoxy resin, and a metal particle layer formed on the resin layer by applying a metal particle dispersion, wherein the metal particle dispersion contains at least metal particles and an additive, and the additive contained in the metal particle layer is also contained in the resin layer.

A method for manufacturing a circuit board according to the present disclosure includes applying a metal particle dispersion containing at least metal particles and an additive to a resin layer containing an epoxy resin to form a metal particle layer; and performing a plating treatment with the additive diffused in the resin layer to form a plating layer on the metal particle layer.

A method for manufacturing a circuit board according to the present disclosure includes applying a metal particle dispersion containing at least metal particles and an additive to a resin layer containing an epoxy resin to form a metal particle layer; and performing an annealing treatment with the additive diffused in the resin layer.

Use of a predetermined metal particle dispersion in the method for manufacturing the circuit board improves the adhesion strength between a metal layer such as a plating layer or a metal particle layer and a resin layer or a substrate layer.

### BRIEF DESCRIPTION OF THE DRAWINGS

FIG. 1 is a view schematically illustrating a layer structure of a laminate of the present disclosure in cross section.

FIG. 2 is an image of a cross section of a circuit board where AFM-IR was performed and infrared absorption spectra.

FIG. 3 is a table showing the relationship between the thickness of a dispersant diffusion layer in a resin layer and adhesion strength.

FIG. 4 is a graph showing the relationship between the thickness of the dispersant diffusion layer in the resin layer and the adhesion strength.

### DETAILED DESCRIPTION

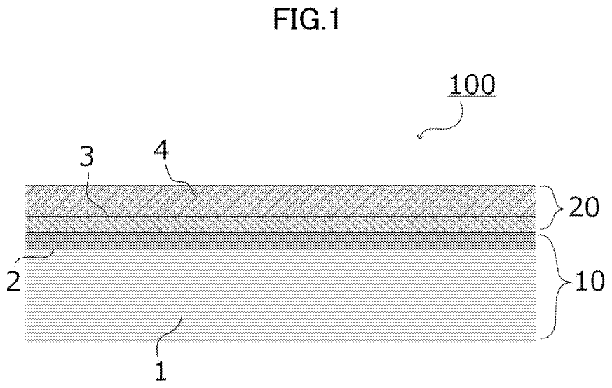

Embodiments of the present disclosure will be described below with reference to the drawings. FIG. 1 is a sectional view schematically illustrating a layer structure of a laminate of the present disclosure that can be used as a circuit board. This drawing illustrates a laminate or a single layer of a circuit board, and the laminate or the circuit board may include a plurality of wiring structures formed by stacking, for example, resin insulator layers and metal conductor layers. For example, the laminate or the circuit board may include a single-sided substrate (single layer substrate), a double-sided substrate (two layer substrate), a four layer substrate, a six layer substrate, an eight layer substrate, or a laminated substrate with more than eight layers.

In FIG. 1, a circuit board 100 includes a laminate 10 and a conductor layer 20 formed on the laminate 10. The laminate 10 includes a substrate layer 1 and a resin layer 2 (which may also be referred to as a primer resin layer for convenience's sake if the substrate layer is made of resin). The conductor layer 20 includes a metal particle layer 3 and a plating layer 4. Such a laminate can be produced by a production method including application of a metal particle dispersion containing at least metal particles, coating molecules for coating the metal particles, an additive as a dispersant, and an organic solvent onto the resin layer 2 to form the metal particle layer. In the present disclosure, the dispersant may be described as an additive.

The laminate or circuit board of the present disclosure is applicable to, for example, printing of a Cu seed layer for wiring, TGV (Through Glass Via: the formation of an insulating layer, a Cu via, and a seed layer), and solder resist printing (solder resist dam), for printed circuit boards (PCB) and package substrates. The present disclosure is also applicable to, for example, the formation of various layers (such as the formation of a bonding material, an insulating layer, a passivation layer, a photoresist, and a peeling layer), flux application, and package marking in advanced packaging technologies.

The present disclosure is also applicable to the formation of a quantum dot layer and the formation of an organic light-emitting diode (OLED) layer in flat panel displays. Further, the present disclosure is also applicable to the formation of a perovskite layer, the formation of electrodes, and the formation of an encapsulation layer in perovskite solar cells.

The substrate layer 1 may be made of, for example, a composite material called FR-4 obtained by impregnating a cloth woven with glass fibers (a glass cloth or a woven glass cloth) with an epoxy resin, a fluorine-based resin (polytetrafluoroethylene, PTFE), a glass cloth base material impregnated with a polyphenylene ether (PPE) resin, glass, a resin substrate made of polyimide, polyester, polyethylene terephthalate, or polyethylene naphthalate, a ceramic substrate such as an alumina substrate, an aluminum nitride substrate, or a sapphire substrate, or a silicon wafer substrate, and may be a material generally considered to be an insulator or a semiconductor in terms of electrical conductivity.

For example, when the material of the substrate layer 1 is rigid, it may have a tensile modulus of 10 GPa or more. The tensile modulus is expressed by using the same physical quantity as the Young's modulus, and can be defined by the Young's modulus. In general, resins and composite materials with a relatively high tensile modulus of about several GPa are called semi-flexible materials, and thus, hard materials with a tensile modulus of 10 GPa or more are called rigid materials. For example, an insulating rigid substrate containing a glass epoxy resin has a tensile modulus of about 20 GPa.

When the material of the substrate layer 1 is flexible, it may be, for example, polyimide, polyamide, polyester such as polyethylene terephthalate (PET) and polyethylene naphthalate (PEN), polyamide synthetic resin which is nylon (registered trademark) specified as nylon 6,10 and nylon 4,6, resins such as polyether ether ketone, acrylonitrile butadiene styrene (ABS), polymethyl methacrylate (PMMA), and polyvinyl chloride, epoxy resins, polystyrene, and polyphenylene sulfide (PPS).

Other examples of the flexible material of the substrate layer 1 may include polyvinylidene chloride, polyvinyl alcohol, styrene-acrylonitrile copolymers, polyethylene, styrene-vinyl acetate copolymers, polyacetal, cellulose acetate, polycarbonate, thermoplastic polyurethane, and polytetrafluoroethylene.

A resin layer 2 is formed on one surface (an upper surface in FIG. 1) of the substrate layer 1 for various purposes, such as improving the coatability of an ink composition which is a metal particle dispersion, modifying the substrate surface, and controlling the behavior of inkjet droplets at the landing.

When a circuit board with traces is formed by an inkjet method, a resin layer 2 that improves adhesion between the substrate layer 1 and a conductor layer 20 formed thereafter may be used. The resin layer 2 preferably has an ink receiving function so that the inkjet droplets containing the metal nanoparticles land in an appropriate size and remain at a desired position without moving after the landing.

The material of the resin layer 2 contains, for example, an epoxy resin, and is adjusted to have a predetermined modulus of elasticity. For example, when the material has a storage modulus of 4.0711×10⁸ Pa or less and a loss modulus of 6.4825×10⁷ Pa or less at 25 °C, it can exhibit a preferable inkjet droplet receiving function. The storage modulus is an index representing the elastic properties of the material. In short, it indicates the ability of the material to store and recover deformation energy, and expresses a spring-like property. The more perfectly elastic the material is, the higher its storage modulus. The loss modulus is an index representing the viscous properties of the material. In short, it indicates the degree to which the material dissipates energy as heat during deformation, and expresses a damper-like property. The more perfectly viscous the material is, the higher its loss storage modulus. The epoxy resin having the storage modulus and the loss modulus in the above ranges has a flexible molecular skeleton and a large free volume, and can facilitate the dispersion of a dispersant in the resin, for example, when combined with dispersants with good compatibility which will be described later.

The epoxy resin is a thermosetting resin having an epoxy group in a molecule, and is chemically stable against alkali when it is cured. As a typical example, the epoxy resin is produced by the condensation reaction of bisphenol A [2,2-bis(4-hydroxyphenyl-propane)] with epichlorohydrin.

Examples of the epoxy resin usable include monomers having one or more epoxy groups in the molecule, polymers thereof, and mixtures thereof. Specific examples of the epoxy resin include biphenyl epoxy resins, bisphenol epoxy resins (bisphenol A epoxy resins, bisphenol F epoxy resins, and tetramethylbisphenol F epoxy resins), stilbene epoxy resins, novolac epoxy resins (phenol novolac epoxy resins and cresol novolac epoxy resins), polyfunctional epoxy resins (triphenolmethane epoxy resins and alkyl-modified triphenolmethane epoxy resins), aralkyl epoxy resins (phenol aralkyl epoxy resins having a phenylene skeleton or a biphenylene skeleton and biphenyl aralkyl epoxy resins), naphthol epoxy resins, triazine nucleus-containing epoxy resins, bridged cyclic hydrocarbon compound-modified phenol epoxy resins (dicyclopentadiene-modified phenol epoxy resins), or derivatives thereof.

The epoxy resin may be, for example, a polyether polyol epoxy resin or an epoxy-modified polyol resin. A polyether polyol may be added to the epoxy resin. The polyether polyol is a polymer compound containing a large number of ether bonds in its molecular structure. The ether bond has two carbon atoms bonded via an oxygen atom, and the carbon atoms on both sides of the oxygen atom are relatively free to rotate, giving high flexibility to the entire molecular chain. Thus, when the polyether polyol is added to the epoxy resin and is contained as a component of the epoxy resin composition, the cured product can have improved flexibility.

The epoxy resin also contributes to improvement in adhesion between the resin layer 2 and metal. During the curing reaction, the epoxy groups open, and hydroxyl groups are formed continuously and regularly. This is a feature not found in other thermosetting resins. The hydroxyl groups form a hydrogen bond with an oxide film on the metal surface and contribute to the adhesion with the metal. Although there are some other modes as well, the interaction is considered to be hydrogen bonding. Alternatively, the same effect as described above can be obtained even when the epoxy structure before the curing reaction has the hydroxyl groups. The epoxy structure also includes aromatic rings and aliphatic ether bonds. The aliphatic ether is a very flexible segment as described above.

The resin layer 2 is formed by applying a resin containing the epoxy resin. The thickness of the resin layer 2 formed on the substrate layer 1 may be, for example, 0.5 μm to 50 μm. The thickness is more preferably 0.5 μm to 30 μm, and still more preferably 1 μm to 20 μm. When the layer is thin, the desired physical properties cannot be easily exhibited. When the layer is thick, the material cost tends to increase, the ratio of the primer to the thickness of the substrate increases, and the substrate properties may not be satisfied. For example, the bending resistance decreases. As will be described later, the resin layer 2 is thicker than the dispersant diffusion layer.

The laminate 10 including the substrate layer 1 and the resin layer 2 may be independently traded as a material for manufacturing the circuit board 100 having the traces formed by an inkjet method. In this case, for example, a protective layer (not shown) may be provided on the surface of the resin layer 2. The protective layer may suitably be as thick as a thin film or a plate. The protective layer may be made of, for example, a metal such as aluminum, and may be aluminum foil or an aluminum film from the viewpoint of ease of drilling. In addition, polypropylene and polyethylene terephthalate may be adopted for antistatic purposes, polyimide may be adopted for high heat resistance, or polyvinyl chloride and polyethylene may be used for general purposes.

The metal particle layer 3 is formed of a metal particle dispersion which is an ink composition discharged from an inkjet head of an inkjet printer. The ink composition contains metal nanoparticles. The metal nanoparticles include nanoparticles of various metals such as gold, silver, platinum, copper, or alloys thereof, and are not technically limited to one metal, but copper nanoparticles are preferred in consideration of conductivity, availability, price, and worldwide supply.

The metal nanoparticles preferably have a mean particle size of 1 nm to 200 nm, more preferably 10 nm to 100 nm. The particles with extremely small sizes may show high reactivity and may decrease the shelf life and stability of the ink. The particles with extremely large sizes may lower the uniformity of the thin film and may easily cause precipitation of the ink particles.

For technical understanding, the ink compositions are simply classified into two types, namely, a particle dispersion ink and a reduction ink, and either type of the ink compositions can be used. It can be said that the particle dispersion ink has properties similar to those of a pigment ink, and the reduction ink has properties similar to those of a dye ink. This classification is merely for convenience. There is also a pyrolytic ink that uses a metal salt or a complex as a precursor and generates metal by pyrolysis, and this can be considered as the reduction ink.

When the particle dispersion ink composition is used, it is necessary to cause the metal nanoparticles to bond, fuse, and contact with each other after the application, in addition to removal of components other than the metal nanoparticles. For example, the printed traces are sintered with light, heat, plasma, or a combination of them so that the metal nanoparticles are fused together for electrical connection to improve the conductivity. Such a treatment may be referred to as a conductivity enhancing treatment by physical sintering. For example, photonic sintering with a flash lamp can be applied.

Further, the conductivity enhancing treatment having the same effect as the sintering can be performed by a chemical reduction treatment. For example, when a reduction reaction of the oxide film on the surface of the copper nanoparticles is caused using a chemical reduction reaction reagent such as formaldehyde, copper oxide is reduced to copper through the reduction reaction, generating copper as an active zero-valent metal. This can cause fusion between the metal nanoparticles similar to the fusion caused by the physical sintering described above. Sintering processes involving chemical reactions or liquid phases, such as liquid phase sintering and reaction sintering, are also known, and they can provide the same effect as the sintering, that is, fusion and bonding of the particles, in the end. Thus, in the present disclosure, the approach by reduction is also regarded as one of the sintering processes in a broad sense.

The reduction ink composition can form a bulk metal by generating fine metal nanoparticles on the spot using a chemical reduction action. The reduction ink composition can be treated at a relatively low temperature. As an example of the reduction ink composition, a copper formate nanoink contains copper formate, alkanolamine, and a solvent having two or more functional groups capable of forming a coordinate bond with copper formate in a molecular structure. In the copper formate ink composition, copper formate is dissolved in an ionic state in the solvent, and is reduced to zero-valent copper by a heat treatment.

As described above, although specific treatments are different depending on the type of the ink composition, their purposes are the same, and these treatments may be collectively referred to as the conductivity enhancing treatment in the present disclosure.

The metal nanoparticles in the ink composition are dispersed in an organic solvent and coated with a coating material. The coating material is used to avoid easy oxidation of the copper nanoparticles, and may be, for example, carboxylic acids, more preferably monocarboxylic acids with an integer carbon number of 6 to 10, such as hexanoic acid, heptanoic acid, octanoic acid, nonanoic acid, or decanoic acid.

The dispersant, which is used to disperse the metal nanoparticles coated with the coating material to form the ink, allows the metal nanoparticles as a dispersoid to be uniformly dispersed in a solvent as a dispersion medium and keeps the metal nanoparticles stably dispersed without aggregation.

The dispersant preferably has functional groups capable of being adsorbed onto the surface of the metal particles, a main chain or a side chain for providing sufficient steric hindrance around the functional groups by solvation and preventing reaggregation, and a skeleton that supports the functional groups and the main or the side chain as necessary in terms of structure.

The following are several examples of the dispersants.

### Dispersant 1: Dispersant Containing Carbonyl Group

A dispersant containing a carbonyl group is a polyalkylene glycol derivative containing the following constitutional units:
(a) a constitutional repeating unit containing an ester bond and having an absorbance peak at 1,730±10 cm⁻¹ in an infrared absorbance spectrum;
(b) a constitutional repeating unit containing a polyoxyalkylene chain; and
(c) a constitutional unit containing a carbonyl group and acting as a site to be adsorbed onto the metal nanoparticles.

The polyoxyalkylene chain as a side chain has affinity for resins, particularly epoxy resins or solvents, and also causes steric repulsion between the metal nanoparticles.

### Dispersant 2: Dispersant Containing Phosphate Ester Groups

A dispersant containing phosphate ester groups contains:
(a) a polyester skeleton;
(b) a plurality of phosphate ester groups chemically bonded to the polyester skeleton; and
(c) a side chain.

### Dispersant 3: Dispersant Containing Ether Group

A dispersant containing an ether group contains:
(a) a polyether main chain consisting of repeating units of ethylene oxide and propylene oxide; and
(b) functional groups introduced along the polyether main chain or at the ends thereof.

The dispersant may be a compound capable of coordinating with copper, and a functional group with a donor atom such as nitrogen, oxygen, sulfur, phosphorus, or carbon is selected. Examples of the nitrogen donor functional group include an amino group, an imino group, a nitrile group, an amide group, a pyridine group, and an imidazole group. Examples of the oxygen donor functional group include a hydroxy group, a phenol group, an alkoxy group, an ether group, a ketone group, a carbonyl group, a phosphate ester group, and a phosphite ester group. Examples of the sulfur donor functional group include a thiol group, a thioether group, and a thioamide group. Examples of the phosphorus donor functional group include a phosphine group. Examples of the carbon donor functional group include an unsaturated hydrocarbon group. The compound may have any functional group included in the group of functional groups described above.

The dispersant may be an oligomer/low molecular weight polymer compound having a weight average molecular weight (Mw) of 1,000 to 10,000, or an oligomer/polymer compound having a weight average molecular weight (Mw) of 1,000 to 200,000. Such a dispersant may be preferable for the resin layer 2 containing the epoxy resin from the viewpoint of the diffusion coefficient and the mesh size.

The dispersant contains a functional group that coordinates with the metal particles and a main chain or a side chain that exhibits steric hindrance, and is contained in the ink composition. Thus, the dispersant is also contained in the landed inkjet droplet layer, and diffused into the resin layer 2 by diffusion after the landing. This will be described later.

The solvent used in the ink composition may be an aqueous solvent or an organic solvent. The organic solvent may be an alcohol solvent or a derivative thereof. More specifically, glycol ethers such as ethylene glycol monoethyl ether, diethylene glycol monobutyl ether, propylene glycol monomethyl ether, or a mixture thereof can be used, and the solvents described below can also be used.

Preferably, an organic solvent containing at least ethylene glycol monomethyl ether, ethylene glycol monoethyl ether, and diethylene glycol butyl ether can be used. These organic solvents exhibit an appropriate swelling ratio in relation to the epoxy resin, and the resin layer 2 can exhibit an appropriate ink receiving function.

Other additives different from the stabilizer and the dispersant may be used.

The ink composition preferably has a viscosity of 1 to 100 mPa·s at a temperature of 25 °C measured by a cone-and-plate viscometer or a rheometer. The viscosity is preferably 1 to 100 mPa·s, more preferably 1 to 50 mPa·s, at a shear rate of 100 (1/S) or more. This is because these conditions are suitable for the environment in which the ink is discharged from the inkjet head, and the ink cannot be easily sprayed from the inkjet head if the viscosity is too high.

When a printing method other than the inkjet method is used, application of the above-described ink composition and metal particle dispersion are possible.

The plating layer 4 is a layer formed by performing electroless or electrolytic plating to further deposit a conductor. Thus, it can be understood that the plating layer 4 is a thick layer of conductor traces, similar to the layer of conductor traces obtained by the conductivity enhancing treatment performed on the metal particle layer 3 (also referred to as a base conductor layer).

In the above-described laminate 10 and circuit board 100, the adhesion between the resin layer 2 and the conductor layer (base conductor layer) formed of the metal particle layer 3 is improved.

### EXAMPLES

Examples of the laminate 10 including the resin layer 2 and the laminate that can be used as the circuit board 100 are described below. Different laminates of Experimental Examples 1 to 9 were prepared to measure adhesion strength. In each sample of the laminates, inkjet droplets were deposited on the entire surface without forming traces, and a plating layer was formed, to measure the adhesion strength. Although no traces are formed, the obtained laminates are referred to as circuit boards for convenience in the description of the examples.

### Example of Ink Composition

An example of the ink used to prepare the circuit board will be described below. In a container, 15 parts of copper nanoparticles, various dispersants, 1 part each, and 82 parts of an organic solvent of glycol ethers described above were blended, and a dispersion process was performed with a planetary centrifugal mixer. Various additives were blended therein in an amount of 0.2 to 1.0 parts, and a dispersion process was performed with the same planetary centrifugal mixer to obtain a coppery-brown, additive-containing copper ink composition. Then, a circuit board was produced using the obtained ink composition.

### Example of (Primer) Resin Layer

As raw materials, a curing agent was mixed with an epoxy resin at a weight ratio of 5% relative to 95% of the epoxy resin, and the mixture was applied to a substrate layer to form a film of 10 μm. Although the ratio of the epoxy resin is not described in detail, five types of epoxy resins, namely, epoxy resins 1 to 5, were used in Experimental Examples 1 to 9. The epoxy resins may be, for example, polyether polyol epoxy resins, and may have an epoxy equivalent weight of 400 to 10,000 g/eq.

### Example of Dispersant (Additive)

As the dispersant, a polyalkylene glycol derivative dispersant containing a carbonyl group (the dispersant 1), a dispersant containing phosphate ester groups (the dispersant 2), and a dispersant containing an ether group (the dispersant 3) were used.

The adhesion strength of the circuit board was evaluated immediately after the fabrication of the laminate, that is, after the plating, and after the annealing of the laminate. The annealing was performed by heating the laminate in an oven at 80 °C for 30 minutes and subsequent heating at 180 °C for 1 hour.

### Peeling Test for Measuring Adhesion Strength

A peeling test was performed on the circuit boards of Experimental Examples 1 to 9 to measure the adhesion strength. The peeling test for checking the adhesion strength of the plating layer to the substrate layer was performed by peeling the plating layer at an angle of 90 degrees according to the UL standards in the United States, for example, UL796F. As the peeling test, peeling was performed several times using test pieces of different widths.

### Method for Measuring Thickness of Dispersant Diffusion Layer

A method for measuring the thickness (μm) of the dispersant layer diffused in the resin layer will be described below. The thickness of the dispersant diffusion layer is measured by acquiring IR spectra of the metal particle layer 3 and the resin layer 2 using an atomic force microscope (AFM-IR) with infrared spectroscopy capabilities. AFM-IR irradiates the sample with pulsed infrared radiation, and specific chemical bonds in the sample absorb the radiation at wavelengths that are resonant to the corresponding vibrational modes. The infrared absorption causes a rapid local temperature rise and an instantaneous expansion of the sample. The force is transmitted to a cantilever, and the magnitude of the vibration of the cantilever is proportional to the local infrared absorption amount. That is, when a strong vibration is detected at a certain wavelength, the wavelength indicates that absorption is caused by a specific molecular vibration (chemical bond) in the sample.

In the examples, the thickness of the dispersant diffusion layer was estimated by determining whether the infrared absorption based on the chemical bond in the dispersant contributing to the adhesion strength occurred or not. First, IR absorption measurement (A0 measurement) was performed at the interface between the metal particle layer and the resin layer in a cross section of the sample as the starting point in the depth direction to obtain a reference value.

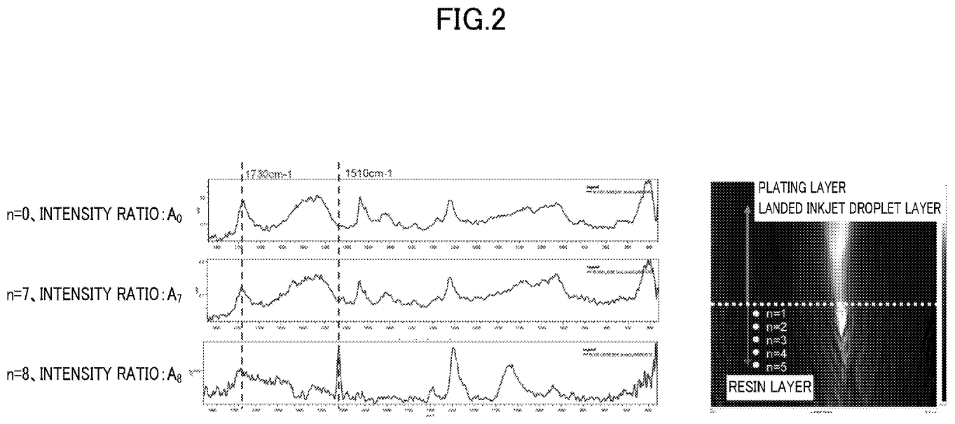

FIG. 2 is an image of a cross section of the circuit board showing the position where AFM-IR was performed and infrared absorption spectra at that position. First, when the specific functional group of the compound contained in the dispersant was a carbonyl group, the ratio A0 of the peak intensity indicating the absorption of the carbonyl group (the highest peak intensity in the range of 1,730±10 cm⁻¹) to a reference peak intensity of the component of the resin layer (the highest peak intensity in the range of 1,510±10 cm⁻¹) was calculated as the strength of the interface as a reference in the depth direction.

Next, on the cross section of the same sample, IR measurement was performed n times (A₁, A₂, . . . , and Aₙ measurements) by shifting the measurement position by 0.2 μm in the depth direction from the interface between the metal particle layer and the resin layer as a starting point. As a result, a spectrum acquisition position n satisfying the requirements of the following expressions (1) and (2) was taken as the thickness of the dispersant diffusion layer in the depth direction starting from the interface between the metal particle layer and the resin layer. The expressions (1) and (2) are satisfied when n is the last position in the depth direction at which the ratio is A₀/3 or more, and the ratio suddenly drops below A₀/3 at the (n+1)th position.

Aₙ≥A₀/3 Expression (1)

Aₙ₊₁≤A₀/3 Expression (2)

Thus, a value obtained by multiplying the last position n (natural number) satisfying the expressions (1) and (2) by 0.2 μm indicates the thickness of the dispersant diffusion layer.

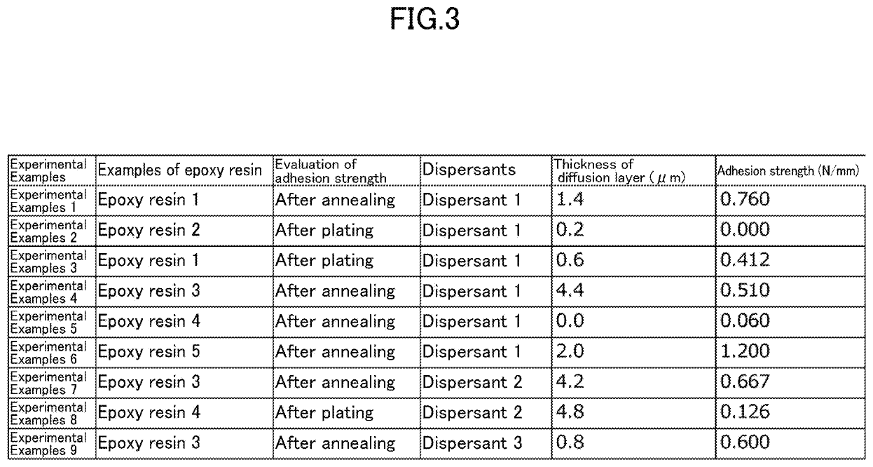

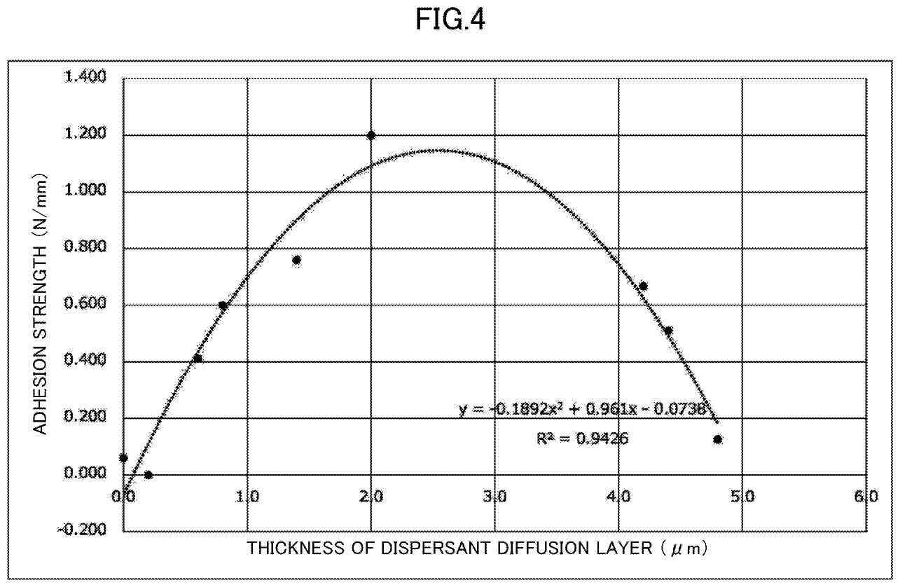

FIG. 3 is a table showing the relationship between the adhesion strength and the thickness of the dispersant diffusion layer obtained by the above measurements for the circuit boards of Experimental Examples 1 to 9, and FIG. 4 shows a graph based on the table of FIG. 3.

In the graph of FIG. 4, the values of Experimental Examples are plotted with the thickness (μm) of the dispersant diffusion layer on the horizontal axis and the adhesion strength (N/mm) on the vertical axis. It is observed from the graph that the circuit board in which the dispersant was diffused to the resin layer had a predetermined adhesion strength. For example, the samples of Experimental Examples 1, 3, 4, 6, 7, and 9 had a high adhesion strength of 0.35 N/mm or more. In particular, the samples of Experimental Examples 1 and 6 had a higher adhesion strength of 0.7 N/mm or more. The adhesion strength of 0.35 N/mm is the minimum standard of the peel strength for certification specified in UL796. The adhesion strength of 0.7 N/mm is a passing threshold of initial adhesion strength under the IPC-6012 standards for internal conductors.

In addition, regardless of the type of the dispersant, a high adhesion strength of 0.6 N/mm or more was measured from the samples of Experimental Examples 7 and 9 using the dispersants 2 and 3 different from the dispersant 1.

High adhesion strengths were observed both after the plating and after the annealing, and a comparison between Experimental Examples 1 and 3 suggests that the annealing increases the thickness of the diffusion layer.

It was observed that the measured adhesion strength increased as the thickness of the dispersant diffusion layer increased, and then decreased. Thus, when an approximate curve fitted by the least squares method is calculated, the following expression is obtained.

y=−0.1892x²+0.961x−0.0738 Expression (3)

According to the approximate curve, the thickness of the diffusion layer having an adhesion strength of 0.35 N/mm or more was 0.5 μm to 4.5 μm. When the thickness is strictly calculated according to the approximate curve, the thickness is 0.48786 μm to 4.59142 μm.

Similarly, according to the approximate curve, the thickness of the diffusion layer having an adhesion strength of 0.7 N/mm or more was 1.0 μm to 4.0 μm. When the thickness is strictly calculated according to the approximate curve, the thickness is 1.00344 μm to 4.07584 μm.

Although the reason why the adhesion strength improved as the thickness of the dispersant diffusion layer increased and then decreased is not clear, but is presumed as follows. The dispersant has affinity for both the metal particles and the resin layer and interacts with them, and thus forms an adhesive layer, exhibiting the adhesion strength. However, if the dispersant is present only at the interface, the adhesive layer is formed thin and easily torn under low energy, resulting in low adhesion strength. When the dispersant is dispersed in a wider range, it means that the adhesive layer is formed thicker and requires more energy to tear, increasing the adhesion strength. On the other hand, when the dispersant is dispersed in a much wider range, the distribution concentration of the dispersant per unit thickness is lowered, and the cohesive energy of the adhesive layer is lowered. As a result, the adhesive layer is easily torn under low energy even if it is formed thicker, resulting in low adhesion strength.

As described above, the adhesion strength between the metal layer such as the plating layer or the metal particle layer and the resin layer or the substrate layer was verified by the examples. In particular, a higher adhesion strength was exhibited when the dispersant was distributed in the resin layer to the depth in a range of 0.5 μm to 4.5 μm from the interface between the metal particle layer and the resin layer as a starting point, and a much higher adhesion strength was exhibited when the dispersant was distributed in the resin layer to the depth in a range of 1.0 μm to 4.0 μm from the starting point.

The embodiments described herein are merely exemplary, and can be modified by various means and structures in order to achieve the functions and obtain some or all of the results and advantages. All of these variations and modifications are considered within the scope of the embodiments described herein. The parameters, dimensions, materials, configurations, etc. described herein are merely exemplary and may be modified depending on the actual application. Those skilled in the art will recognize, or be able to ascertain using no more than routine experimentation, many equivalents to the specific implementations described herein. Thus, the foregoing embodiments are merely examples, and embodiments including aspects not explicitly described herein are also possible within the scope of the claims of the present application and their equivalents. The present disclosure includes features, systems, articles, materials, kits, and methods described in the present specification, and all aspects obtained by combining the features, systems, articles, materials, kits, and methods within a range not mutually contradictory.

For example, some embodiments may include the following aspects.
[1]
A laminate, including:
a resin layer containing an epoxy resin; and
a metal particle layer formed on the resin layer by applying a metal particle dispersion,
wherein
the metal particle dispersion contains at least metal particles and an additive, and
the additive contained in the metal particle layer is also contained in the resin layer.
[2]
The laminate of [1], wherein
the additive is distributed in the resin layer to a depth in a range of 0.5 μm to 4.5 μm from an interface between the metal particle layer and the resin layer as a starting point.
[3]
The laminate of [2], wherein
the additive is distributed in the resin layer to a depth in a range of 1.0 μm to 4.0 μm from the interface between the metal particle layer and the resin layer as the starting point.
[4]
The laminate of [3], wherein
the resin layer has a thickness of 0.5 μm to 50 μm.
[5]
The laminate of [2], wherein
the metal particles are copper particles having a mean particle size of 1 nm to 200 nm,
the additive is a compound capable of coordinating with copper, and
the additive contains any one of functional groups included in the group consisting of an amino group, an imino group, a nitrile group, an amide group, a pyridine group, an imidazole group, a hydroxy group, a phenol group, an alkoxy group, an ether group, a ketone group, a carbonyl group, a phosphate ester group, a phosphite ester group, a thiol group, a thioether group, a thioamide group, a phosphine group, and an unsaturated hydrocarbon group.
[6]
The laminate of [5], wherein
the functional group is any one of the carbonyl group, the phosphate ester group, and the ether group.
[7]
The laminate of [6], wherein
the additive is an oligomer/polymer compound containing a main chain or a side chain and having a weight average molecular weight (Mw) of 1,000 to 200,000.
[8]
The laminate of any one of [1] to [7], wherein
the resin layer has a storage modulus of 4.0711×10⁸ Pa or less and a loss modulus of 6.4825×10⁷ Pa or less at 25 °C.
[9]
A method for manufacturing a circuit board, including:
applying a metal particle dispersion containing at least metal particles and an additive to a resin layer containing an epoxy resin to form a metal particle layer; and
performing a plating treatment with the additive diffused in the resin layer to form a plating layer on the metal particle layer.
[10]
A method for manufacturing a circuit board, including:
applying a metal particle dispersion containing at least metal particles and an additive to a resin layer containing an epoxy resin to form a metal particle layer; and
performing an annealing treatment with the additive diffused in the resin layer.

The aspects [1] to [10] described above can be combined in any manner. For example, at least some of the features of the aspect [2] and other aspects may be combined with all or some of the features of the aspect [1]. Any features extracted from the aspects [1] to [10] may be combined. The applicant of the present application intends to claim rights to the invention including these features. Although the description includes phrases such as “in the case of . . . ” or “when . . . ,” it does not imply that the description is limited to those specific cases or situations. These are examples of preferred configurations, and the applicant intends to claim rights to configurations that differ from these examples. Although the description includes a specific order, the present disclosure is not limited to that order. The present disclosure also discloses configurations in which some features are deleted or the order is changed, and the applicant intends to claim the rights to such configurations.

What is claimed is:

1. A laminate, comprising:
a resin layer containing an epoxy resin; and
a metal particle layer formed on the resin layer by applying a metal particle dispersion,
wherein
the metal particle dispersion contains at least metal particles and an additive, and
the additive contained in the metal particle layer is also contained in the resin layer.

2. The laminate of claim 1, wherein
the additive is distributed in the resin layer to a depth in a range of 0.5 μm to 4.5 μm from an interface between the metal particle layer and the resin layer as a starting point.

3. The laminate of claim 2, wherein
the additive is distributed in the resin layer to a depth in a range of 1.0 μm to 4.0 μm from the interface between the metal particle layer and the resin layer as the starting point.

4. The laminate of claim 3, wherein
the resin layer has a thickness of 0.5 μm to 50 μm.

5. The laminate of claim 2, wherein
the metal particles are copper particles having a mean particle size of 1 nm to 200 nm,
the additive is a compound capable of coordinating with copper, and
the additive contains any one of functional groups included in the group consisting of an amino group, an imino group, a nitrile group, an amide group, a pyridine group, an imidazole group, a hydroxy group, a phenol group, an alkoxy group, an ether group, a ketone group, a carbonyl group, a phosphate ester group, a phosphite ester group, a thiol group, a thioether group, a thioamide group, a phosphine group, and an unsaturated hydrocarbon group.

6. The laminate of claim 5, wherein
the functional group is any one of the carbonyl group, the phosphate ester group, or the ether group.

7. The laminate of claim 6, wherein
the additive is an oligomer/polymer compound containing a main chain or a side chain and having a weight average molecular weight (Mw) of 1,000 to 200,000.

8. The laminate of claim 1, wherein
the resin layer has a storage modulus of 4.0711×10⁸ Pa or less and a loss modulus of 6.4825×10⁷ Pa or less at 25 °C.

9. A method for manufacturing a circuit board, comprising:
applying a metal particle dispersion containing at least metal particles and an additive to a resin layer containing an epoxy resin to form a metal particle layer; and
performing a plating treatment with the additive diffused in the resin layer to form a plating layer on the metal particle layer.

10. A method for manufacturing a circuit board, comprising:
applying a metal particle dispersion containing at least metal particles and an additive to a resin layer containing an epoxy resin to form a metal particle layer; and
performing an annealing treatment with the additive diffused in the resin layer.
